(19) United States
(12) Patent Application Publication
(10) Pub. No.: US 2011/0067996 A1
(43) Pub. Date: Mar. 24, 2011

(54) PVD METHOD FOR DEPOSITING A COATING ONTO A BODY AND COATED BODIES MADE THEREOF

(75) Inventors: Maria ÅSTRAND, Sollentuna (SE); Mats AHLGEN, Taby (SE); Helen BLOMQVIST, Enskede Gard (SE)

(73) Assignee: Sandvik Intellectual Property AB, Sandviken (SE)

(21) Appl. No.: 12/884,778

(22) Filed: Sep. 17, 2010

(30) Foreign Application Priority Data
Sep. 18, 2009 (EP) 09011915.7

(51) Int. Cl. C23C 14/14

(52) U.S. Cl. 204/192.15

(57) ABSTRACT

A method of making a coated body including a coating and a substrate where, onto said substrate, a coating is deposited, using a PVD deposition process. The coating includes a nitride, carbide, oxide, boride or mixtures thereof, of one or more elements selected from groups IVb, Vb, VIb of the periodic table and Al, Y and Si. The deposition process includes at least one sequence of varying the substrate bias voltage, while maintaining the active targets. The sequence of varying the substrate bias voltage includes a subsequence Sᵢ including depositing at a first substrate bias voltage, Bᵢ, for a deposition time, Tᵢ, of between 10 seconds and 60 minutes, then, during a ramping time, Rᵢ, of between 10 seconds and 40 minutes, while depositing, gradually changing the substrate bias voltage to a second substrate bias voltage Bᵢ₊₁, where |Bᵢ−Bᵢ₊₁|≧10 V. The subsequence, Sᵢ, is repeated until i=n where i=0, 1, 2, . . . n, where n≧2, and where each new subsequence starts the deposition at the same substrate bias voltage used when ending the previous subsequence.

### FIELD OF INVENTION

The present disclosure relates to a method of making a coated body using a PVD-method. The PVD-method includes a sequence varying the substrate bias voltage. The present disclosure also relates to a coated body made according to the method.

### BACKGROUND

PVD coatings, especially on cutting tools, are well known in the art. The most commonly known PVD techniques are arc evaporation and magnetron sputtering. It is known in the art to vary the substrate bias voltage depending on the coating composition. Different target compositions can require different substrate bias voltages.

Another PVD depositing technique where the substrate bias voltage is varied is the uni- and bipolar pulsed techniques where the substrate bias voltage is varied at a high frequency.

US 2007/0275179 A1 discloses deposition of an aperiodic, multilayered coating having a MX/LX/MX/LX . . . laminar structure. The coating produced contains at least one electrically isolating layer. The coating is deposited with Bipolar Pulsed Dual Magnetron Sputtering (BPDMS) where the pulse times are in the range of μs.

Variations of the substrate bias voltage in order to improve PVD coatings have also been tested.

US2007/0218242 discloses a PVD-coating having variations in compressive stress within the coating. The compressive stress variation is obtained by varying the substrate bias voltage.

It is desired to obtain a coating having an improved wear resistance.

There is a constant strive to further improve the properties of PVD coatings to meet the increasing demands on improved wear resistance and increased tool life.

It is further desired to obtain a coating having an increased tool life.

### BRIEF DESCRIPTION OF THE FIGURES

FIG. 1a-1e shows different embodiments of the present invention where the substrate bias is varied in different patterns.

FIG. 2 is a schematic drawing of one embodiment of the present invention showing as it would look like in a Scanning Electron Microscope.

### DETAILED DESCRIPTION OF PREFERRED EMBODIMENTS

Applicants discovered that improved wear resistance and increased tool life can be obtained by depositing a PVD coating by applying a sequence varying the substrate bias voltage in a certain pattern.

An aspect of the present invention relates to a method of making a coated body including a coating and a substrate where onto the substrate a coating is deposited, using a PVD deposition process. The coating includes a nitride, carbide, oxide, boride or mixtures thereof, of one or more elements selected from groups IVb, Vb, VIb of the periodic table and Al, Y and Si. The deposition process includes at least one sequence of varying the substrate bias voltage, while maintaining the active targets, where the sequence of varying the substrate bias voltage includes a subsequence Sᵢ of:

depositing at a first substrate bias voltage, Bᵢ, for a deposition time, Tᵢ, of between 10 seconds and 60 minutes, then, during a ramping time, Rᵢ, of between 10 seconds and 40 minutes, while depositing, gradually changing the substrate bias voltage to a second substrate bias voltage Bᵢ₊₁, where |Bᵢ−Bᵢ₊₁|≧10 V,

the subsequence, Sᵢ, is repeated until i=n where i=0, 1, 2, . . . n, where n≧2, and where each new subsequence starts the deposition at the same substrate bias voltage used when ending the previous subsequence.

The value n is suitably 2≦n≦1000, more particularly 6≦n≦100 and yet more particularly 10≦n≦20.

The substrate bias voltage Bᵢ₌₁, Bᵢ₌₂ etc. is suitably between −10 and −300 V and particularly between −20 and −200 V.

The difference between the first and second substrate bias voltage in absolute value, |Bᵢ₊₁−Bᵢ| is preferably ≧40 V and more particularly ≧70 V, but ≦290 V.

The deposition time, Tᵢ, is preferably between 30 seconds and 30 minutes and more particularly between 1 and 15 minutes.

The ramping time, is preferably between 20 seconds and 20 minutes and more particularly between 30 seconds and 10 minutes.

As used herein, “by gradually changing the substrate bias voltage” refers to changing the substrate bias voltage either continuously or incrementally.

During the deposition process the active targets are maintained. Maintaining the active targets refers to continued use of the same targets through out the sequence of varying the substrate bias voltage.

In one embodiment, the sequence includes two different subsequences, A and B, alternated through out the whole sequence of varying the substrate bias voltage. The two subsequences will then be:

A: Depositing at a substrate bias voltage, B₁, for a deposition time, T₁, of between 10 seconds and 60 minutes, then, during a ramping time, R₁, of between 10 seconds and 40 minutes, while depositing, gradually changing the substrate bias voltage to a substrate bias voltage, B₂,

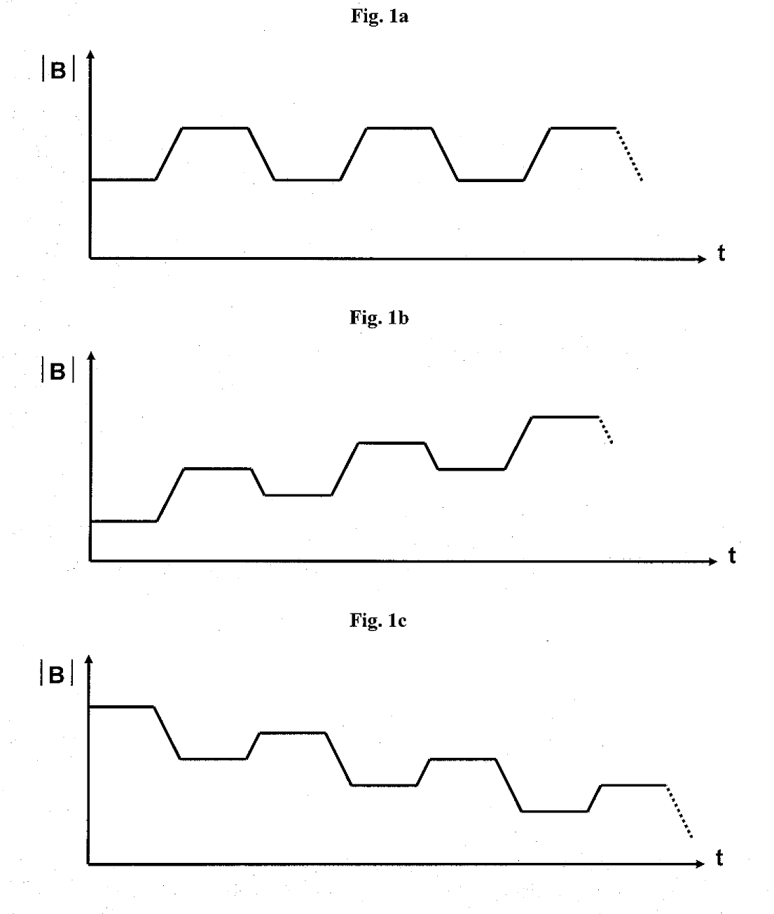

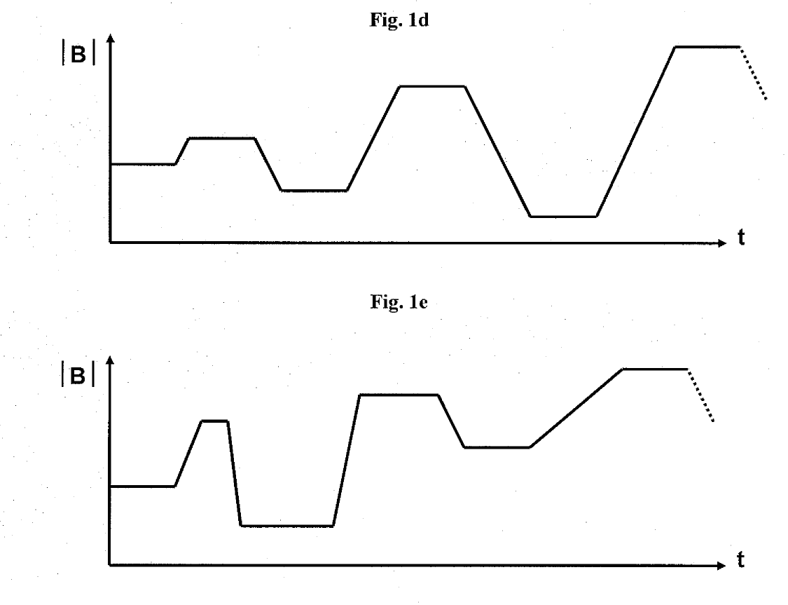

B: Depositing at the substrate bias voltage, B₂, for a deposition time, T₂, of between 10 seconds and 60 minutes, then, during a ramping time, R₂, of between 10 seconds and 40 minutes, while depositing, gradually changing the substrate bias voltage to a substrate bias voltage B₁, where |B₁−B₂|≧10 V. The subsequences A and B are alternated. One example of this embodiment is shown in FIG. 1a.

In yet another embodiment, the sequence of varying the substrate bias voltage is built up by subsequences such that the substrate bias voltage during deposition at deposition time Tᵢ in the first, third, fifth etc. subsequence is gradually increasing while the substrate bias voltage during deposition at deposition time Tᵢ in the second, fourth, sixth etc. subsequence is also gradually increasing. One example of this embodiment is shown in FIG. 1b.

In yet another embodiment, the sequence of varying the substrate bias voltage is built up by subsequences such that the substrate bias voltage during deposition at deposition time Tᵢ in the first, third, fifth etc. subsequence is gradually decreasing while the substrate bias voltage during deposition at deposition time Tᵢ in the second, fourth, sixth etc. subsequence is also gradually decreasing. One example of this embodiment is shown in FIG. 1c.

In yet another embodiment, the absolute value, |Bᵢ−Bᵢ₊₁| is increasing for each subsequence. One example of this embodiment is shown in FIG. 1d.

In yet another embodiment, the sequence is built such that substrate bias voltages, deposition times and ramping times are varied randomly. One example of this embodiment is shown in FIG. 1e.

The method can also include a mixture of one or more of the above described embodiments.

The composition of the coating deposited is determined by the target composition and the process gas present in the deposition chamber. The coating deposited, including, for example during the at least sequence of varying the substrate bias voltage, is suitably a nitride, carbide, oxide, boride or mixtures thereof of one or more elements selected from groups IVb, Vb, VIb of the periodic table and Al, Y and Si. In particular embodiments, the coating deposited is a nitride of one or more elements selected from groups IVb, Vb, VIb of the periodic table and Al, Y and Si, and in more particular embodiments, a nitride of one or more of Ti, Al, Cr, Si and Y.

In one embodiment, the coating deposited is (Ti,Al)N. In a certain embodiment, the (Ti,Al)N composition is (Ti₁₋ₓAlₓ)N, where x suitably is between 0.2 and 0.9, particularly between 0.4 and 0.8, and more particularly between 0.5 and 0.7.

In another embodiment, the coating deposited is (Ti,Al,Cr)N. In a certain embodiment, the (Ti,Al)N composition is (Al_{1-x-y}TiₓCr_{y})N where x is between 0.05 and 0.25, particularly between 0.10 and 0.20, and where y is between 0.05 and 0.30, particularly between 0.10 and 0.25, and 0.30<x+y<0.70.

In yet another embodiment, the coating deposited is (Ti,Al,Cr,Si)N.

The method can be applied to all common PVD techniques, like cathodic arc evaporation, magnetron sputtering, high power pulsed magnetron sputtering (HPPMS), ion plating etc., in particular cathodic arc evaporation or magnetron sputtering. Process parameters, other than the substrate bias voltage, can be conventional in the art for depositing PVD-coatings onto substrates and depend on the specific deposition equipment, coating composition etc. Typically, the deposition temperature varies between 100 and 900° C.

The pressure during deposition is typically between 0.1 to 10 Pa of the process gas present. The process gas can be one or more of O₂, N₂, Ar, C₂H₂, CH₄ or silicon containing gases like, for example, trimethylsilane, depending on the aimed coating composition.

Suitable substrates include cutting tools, like cutting tool inserts, or round tools such as drills, end mills, taps etc. In certain embodiments, the substrate is made of any of cemented carbide, cermets, ceramics, cubic boron nitride, polycrystalline diamond or high speed steels. In more certain embodiments, the substrate is made of cemented carbide.

In one embodiment, the substrate can be pre-coated with an inner layer deposited directly onto the substrate to ensure a good adhesion to the substrate. The inner layer can include a pure metal and/or a nitride, particularly Cr, Ti, CrN or TiN. The inner layer can have a thickness of 0.005-0.5 μm, particularly 0.02-0.2 μm, and is deposited within the same coating process as the rest of the coating.

In one embodiment, the method can further include deposition of other PVD layers without the sequence of varying the substrate bias voltage, including, for example, at conventional deposition conditions. These additional deposition sequences can be performed either prior to or after the sequence with varying the substrate bias voltage. These additional deposition sequences can take place in the same deposition apparatus as the rest of the deposition steps.

In one embodiment, the method can further include one or more additional sequences where the active targets are changed between each sequence, including, for example, where during the sequence of varying the substrate bias voltage the active targets do not change, but the active targets are changed if a new sequence is started.

The total coating thickness is between 0.5 and 20 μm, particularly between 0.5 and 8 μm and more particularly between 1 and 6 μm.

All thicknesses given herein refer to measurements conducted on a reasonably flat surface being in direct line of sight from the targets. For inserts, being mounted on sticks during deposition, it means that the thickness has been measured on the middle of a side directly facing the target. For irregular surfaces, such as those on for example, drills and end mills, the thicknesses given herein refer to the thickness measured on any reasonably flat surface or a surface having a relatively large curvature and some distance away from any edge or corner. For example, on a drill, the measurements have been performed on the periphery, and on an end mill the measurements have been performed on the flank side.

In one embodiment, the method further includes a post treatment step. The post treatment step can for example, be brushing, blasting, shot peening, etc.

In one embodiment, the sequence of varying the substrate bias voltage is as follows:

a) Deposition at a substrate bias voltage of between −120 to −80 V, particularly between −110 and −90 V for a period of 2 to 10 minutes, particularly between 4 and 8 minutes;

b) During a period of 30 seconds and 4 minutes, particularly between 1 and 3 minutes, increasing the substrate bias voltage to −220 to −180 V, particularly between −210 and −190 V;

c) Deposition at a substrate bias voltage of between −220 to −180 V, particularly between −210 and −190 V for a period of 2 to 10 minutes, particularly between 4 and 8 minutes;

d) During a period of 30 seconds and 4 minutes, particularly between 1 and 3 minutes, decreasing the substrate bias voltage to −120 to −80 V, particularly between −110 and −90 V;

Where step a) to d) is repeated until the desired coating thickness is reached.

In yet another embodiment, the sequence of varying the substrate bias voltage is as follows:

a) Deposition at a substrate bias voltage of between −90 to −60 V, particularly between −80 and −70 V for a period of 2 to 10 minutes, particularly between 4 and 8 minutes;

b) During a period of 30 seconds and 4 minutes, particularly between 1 and 3 minutes, increasing the substrate bias voltage to −170 to −130 V, particularly between −160 and −140 V;

c) Deposition at a substrate bias voltage of between −170 to −130 V, particularly between −160 and −140 V; for a period of 2 to 10 minutes, particularly between 4 and 8 minutes;

d) During a period of 30 seconds and 4 minutes, particularly between 1 and 3 minutes, decreasing the substrate bias voltage to −90 to −60 V, particularly between −80 and −70 V;

Where step a) to d) is repeated until the desired coating thickness is reached.

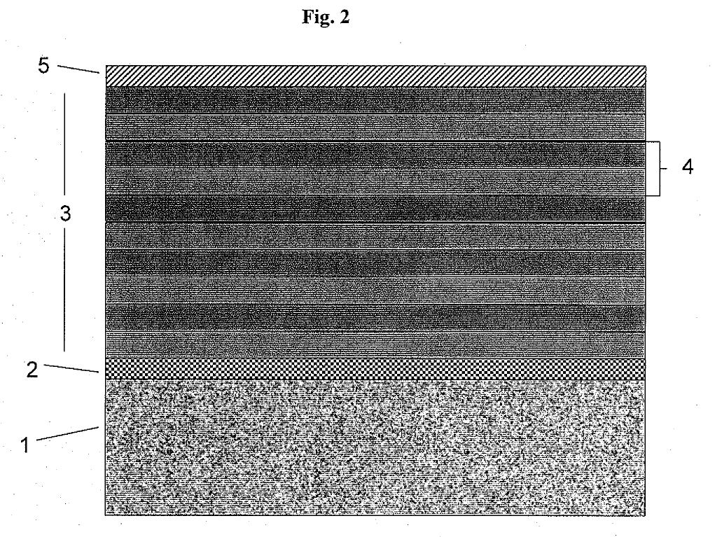

Another aspect of the invention relates to coated bodies made according to embodiments of the method described above. The sequences varying the bias are displayed as a layered structure which can be seen when using Scanning Electron Microscopy (SEM) or Transmission Electron Microscopy (TEM). For example, FIG. 2 shows a substrate (1), pre-coated with an inner layer (2), a coating deposited according to an embodiment of the present invention (3) and an outer layer (5). The coating (3) includes sequences (4) varying the substrate bias, and has a layered appearance.

### Example 1

Cemented carbide end mills with the geometry R216.34-10050-BC22P were coated with PVD arc evaporation using Ti_{0.33}Al_{0.67}-targets. The substrates were first subjected to an etching process, prior to deposition of a starting layer of Ti having a thickness of approximately 0.050 μm.

After that, deposition of the (Ti,Al)N coating took place. The coating was deposited at a temperature of 600° C. and at a N₂ pressure of 1.0 Pa. The substrate bias voltage was varied according to the following sequence:

a) Deposition at −100V for 6 minutes

b) During a period of 2 minutes, increasing the substrate bias voltage to −200 V

c) Deposition at −200V for 6 minutes

d) During a period of 2 minutes, decreasing the substrate bias voltage to −100 V

Steps a) to d) were repeated until the coating reached a coating thickness on the flank side of 2.8 μm.

The end mills are herein referred to as Invention Example 1.

### Example 2

Cemented carbide end mills of the same geometry and composition as in Example 1 were coated with PVD arc evaporation using Ti_{0.33}Al_{0.67}-targets. The substrates were first subjected to an etching process, prior to depositing a starting layer of Ti having a thickness of approximately 0.050 μm. After that, deposition of the (Ti,Al)N coating took place. The coating was deposited at a temperature of 600° C., at a N₂ pressure of 1.0 Pa, and at a constant substrate bias voltage of 100 V until a final coating thickness of 3.8 μm was reached. The end mills according to Example 2 are herein referred to as Reference 1.

### Example 3

End mills according to Examples 1 and 2 respectively, were tested in a semi-finishing cutting operation in steel at the following cutting conditions:

Material: SS2244

Quantification: milled length

V_{c}=300 m/min

aₚ=10 mm

aₑ=1 mm

f_{z}=0.1 mm/tooth

Note: Coolant

Tool life criterion: Vb/Vbₘₐₓ≧0.15/0.20

A third variant, Comparative 1, of the same cemented carbide end mill as in Examples 1 and 2 (composition and geometry), which had been deposited by an external supplier with a homogenous Al₆₅Ti₃₅N layer as analyzed with EDS and with a thickness of 3.2 μm on the flank side was also included as reference. Three end mills of each variant were tested and the results in Table 1 give the average of the three:

TABLE 1

| | Tool life (m) |
|---|---|
| Invention Example 1 | 323 |
| Reference 1 | 217 |
| Comparative 1 | 220 |

Table 1 clearly shows that the end mills of Invention Example 1, have a considerably longer tool life than prior art, including, for example, Reference 1 and Comparative 1.

### Example 4

End mills according to Examples 1 and 2 were tested in a semi-finishing cutting operation in stainless steel at the following cutting conditions:

Material: 316Ti

Quantification: maximum wear in mm at 200 meters milled length

V_{c}=105 m/min

aₚ=10 mm

aₑ=1 mm

f_{z}=0.071 mm/tooth

Note: Coolant

A third variant, Comparative 1, of the same cemented carbide end mill as in Examples 1 and 2 (composition and geometry), which had been deposited by an external supplier with a homogenous Al₆₅Ti₃₅N layer as analyzed with EDS and with a thickness of 3.2 μm on the flank side was also included as reference. Two end mills of each variant were tested and the results in Table 2 give the average of the two:

TABLE 2

| | Max wear (mm) |
|---|---|
| Invention Example 1 | 0.10 |
| Reference 1 | 0.16 |
| Comparative 1 | 0.17 |

Table 2 clearly shows that the end mills of Invention Example 1, have a considerably better wear resistance, including, for example, a lower maximum wear, than both Reference 1 and Comparative 1.

### Example 5

Threading inserts of the geometry, 266RG-16MM01A150M, were coated according to the method described in Example 1 to a coating thickness of 2.3 μm and according to the method in Example 2 to a coating thickness of 2.1 μm, respectively. They are herein referred to as Invention Example 2 and Reference 2. They were tested in an intermittent threading application as follows:

Material: SS2541

Quantification: Number of threads

V_{c}=110 m/min

number of passes=8

Length of thread=25 mm

Tool life criterion: Vb/Vbₘₐₓ≧0.15 mm

Two inserts of each variant were tested and the results in Table 3 give the average of the two:

TABLE 3

| | Tool life (number of threads) |
|---|---|
| Invention Example 2 | 115 |
| Reference 2 | 65 |

Table 3 clearly shows that the threading inserts of Invention Example 2, have a longer tool life than prior art inserts, including, for example, Reference 2.

### Example 6

Cemented carbide threading inserts with the geometry R166.OG-16VM01-002 were coated using PVD arc evaporation with Ti_{0.30}Al_{0.70}-targets and Cr₃₀Al₇₀-targets. The substrates were first subjected to an etching process, prior to depositing a starting layer of TiN having a thickness of approximately 0.10 μm.

After that, deposition of the (Ti,Cr,Al)N coating took place. The coating is deposited at temperature of 600° C. and at a N₂ pressure of 1.0 Pa. The 3-fold rotation of the substrates resulted in alternating layers of TiAlN and AlCrN with sublayer thicknesses in the range of 0.2 nm to 30 nm. The substrate bias voltage was varied according to the following sequence:

a) Deposition at −75 V for 6 minutes

b) During a period of 2 minutes, increasing the substrate bias voltage to −150 V

c) Deposition at −150 V for 6 minutes

d) During a period of 2 minutes, decreasing the substrate bias voltage to −75 V

Steps a) to d) were repeated until the coating reached a coating thickness on the flank face of 2.2 μm. The deposition cycle was ended with a thin TiN color layer of approximately 0.2 μm. The threading inserts are herein referred to as Invention Example 3.

### Example 7

Cemented carbide threading inserts with the geometry R166.OG-16VM01-002 were deposited with TiN at 450° C. using an ion plating method. The threading inserts are herein referred to as Reference 3.

### Example 8

Threading inserts of Examples 6 and 7, and threading inserts with the same geometry but deposited according to Example 1, referred to herein as Invention Example 4, were tested in a threading operation as follows:

Material: 316Ti

Quantification: Number of threads

V_{c}=90 m/min

Number of passes=14

Length of thread=30 mm

Tool life criterion: Vb/Vbₘₐₓ≧0.15 mm

Two threading inserts of each variant were tested and the results in Table 4 give the average of the two:

TABLE 4

| | | Tool life |
|---|---|---|
| | Coating thickness (μm) | (number of threads) |
| Invention Example 3 | 2.2 | 96 |
| Invention Example 4 | 2.3 | 96 |
| Reference 3 | 2.8 | 45 |

Table 4 clearly shows that the threading inserts of Invention Example 3 and Invention Example 4, have a considerably longer tool life than prior art, including, for example, Reference 3.

1. A method of making a coated body comprising providing a substrate, onto said substrate deposit, using a PVD deposition process, a coating comprising a nitride, carbide, oxide, boride or mixtures thereof, of one or more elements selected from groups IVb, Vb, VIb of the periodic table and Al, Y and Si,
wherein the deposition process comprises at least one sequence of varying the substrate bias voltage, while maintaining the active targets, wherein the sequence of varying the substrate bias voltage comprises a subsequence Sᵢ of:
depositing at a first substrate bias voltage, Bᵢ, for a deposition time, Tᵢ, of between 10 seconds and 60 minutes, then, during a ramping time, of between 10 seconds and 40 minutes, while depositing, gradually changing the substrate bias voltage to a second substrate bias voltage Bᵢ₊₁, where |Bᵢ−Bᵢ₊₁|≧10 V,
the subsequence, Sᵢ, is repeated until i=n where i=0, 1, 2, . . . n, where n≧2, and where each subsequence starts the deposition at the same substrate bias voltage used when ending the previous subsequence.

2. A method according to claim 1, wherein |Bᵢ₊₁−Bᵢ|, is ≧40 V.

3. A method according to claim 2, wherein |Bᵢ₊₁−Bᵢ|, is ≧70 V.

4. A method according to claim 1, wherein 2≦n≦1000.

5. A method according to claim 1, wherein the substrate bias voltage Bᵢ is between −10 and −300 V.

6. A method according to claim 1, wherein deposition time, Tᵢ, is between 30 seconds and 30 minutes.

7. A method according to claim 1, wherein the ramping time, Rᵢ, is between 20 seconds and 20 minutes.

8. A method according to claim 1, wherein the coating deposited during the at least one sequence of varying the substrate bias voltage is a nitride of one or more elements selected from groups IVb, Vb, VIb of the periodic table and Al, Y and Si.

9. A method according to claim 1, wherein the coating deposited during the at least one sequence of varying the substrate bias voltage is (Ti,Al)N.

10. A method according to claim 1, wherein the coating deposited during the at least one sequence of varying the substrate bias voltage is (Ti,Al,Cr)N.

11. A method according to claim 1, wherein the coating is further subjected to a post treatment step.

12. A method according to claim 1, wherein the body is a cutting tool.

13. A coated body made according to the method in claim 1.

14. A coated body according to claim 12, wherein the body is a cutting tool.
